(19) United States
(12) Patent Application Publication
(10) Pub. No.: US 2026/0141972 A1
(43) Pub. Date: May 21, 2026

(54) FUNNEL-LIKE SHAPE INPUT/OUTPUT REPAIR MECHANISM CAPABLE OF SIMPLIFYING TRACE ROUTING DESIGN

(71) Applicant: PieceMakers Technology, Inc., Hsinchu City (TW)

(72) Inventors: Tah-Kang Joseph Ting, Hsinchu City (TW); Gyh-Bin Wang, Hsinchu City (TW); Che-Sheng Yu, Hsinchu City (TW)

(73) Assignee: PieceMakers Technology, Inc., Hsinchu City (TW)

(21) Appl. No.: 19/390,682

(22) Filed: Nov. 17, 2025

Related U.S. Application Data
(60) Provisional application No. 63/722,604, filed on Nov. 20, 2024.

(51) Int. Cl. G11C 29/44; G11C 29/02; G11C 29/14

(52) U.S. Cl. CPC G11C 29/44; G11C 29/022; G11C 29/14

(57) ABSTRACT

A memory device includes a memory cell array, an internal logic circuit having a first set of data paths, a second set of data paths, a multiplexer circuit, a storage circuit, and a decoder. The memory cell array is used for storing data. The multiplexer circuit is disposed between the first set of data paths and the second set of data paths. The storage circuit is used for storing g fault information associated with the first set of data paths. The decoder is used for reading and decoding the fault information and for controlling the multiplexer circuit to select a neighboring non-faulty data path to form a connection with a data path based on the fault information if a specific data path is faulty, so as to form a funnel-like shape connection structure.

### CROSS REFERENCE TO RELATED APPLICATIONS

This application claims the benefit of U.S. Provisional Application No. 63/722,604, filed on Nov. 20, 2024. The content of the application is incorporated herein by reference.

### BACKGROUND OF THE INVENTION

### 1. Field of the Invention

The invention relates to an input/output data path repair mechanism, and more particularly to a memory device and an input/output data path repair method of the memory device.

### 2. Description of The Prior Art

Generally speaking, a conventional input/output (I/O) repair scheme may utilize a portion of redundant I/O pads as a repair solution to directly replace a portion of main I/O pads (which are faulty/defective pads) of a conventional memory device. That is, the physical connections of the faulty main I/O pads are directly replaced by those of the redundant I/O pads. The disadvantage of the conventional input/output (I/O) repair scheme is that it is difficult to design the trace routing between the I/O pads after being repaired. The conventional input/output (I/O) repair scheme cannot be applied into a wide I/O interface architecture/system that may use a very large number of parallel I/O pas/pins to transfer a massive amount of data simultaneously.

### SUMMARY OF THE INVENTION

Therefore one of the objectives of the invention is to provide a memory device and an input/output data path repair method of the memory device to solve the above-mentioned problems.

According to embodiments of the invention, a memory device is disclosed. The memory device comprises a memory cell array, an internal logic circuit having a first set of data paths, a second set of data paths, a multiplexer circuit, a storage circuit, and a decoder. The memory cell array is used for storing data. The internal logic circuit having a first set of data paths is coupled to the memory cell array. The number of the second set of data paths is smaller than a number of the first set of data paths. The multiplexer circuit is disposed between the first set of data paths and the second set of data paths. The storage circuit is used for storing at least one set of bits indicating fault information associated with the first set of data paths. The decoder, coupled to the storage circuit, is used for reading and decoding the at least one set of bits from the storage circuit to obtain the fault information and for controlling the multiplexer circuit to select a neighboring non-faulty data path in the first set of data paths to form a connection with a data path in the second set of data paths based on the fault information if a specific data path in the first set of data paths is faulty, so as to form a funnel-like shape connection structure between the first set of data paths and the second set of data paths.

According to the embodiments of the invention, an input/output data path repair method of a memory device is disclosed. The input/output data path repair method comprises: providing a memory cell array for storing data; providing an internal logic circuit having a first set of data paths which is coupled to the memory cell array; providing a second set of data paths, a number of the second set of data paths being smaller than a number of the first set of data paths; providing a multiplexer circuit which is disposed between the first set of data paths and the second set of data paths; providing a storage circuit for storing at least one set of bits indicating fault information associated with the first set of data paths; and, using a decoder to read and decode the at least one set of bits from the storage circuit to obtain the fault information and to control the multiplexer circuit to select a neighboring non-faulty data path in the first set of data paths to form a connection with a data path in the second set of data paths based on the fault information if a specific data path in the first set of data paths is faulty, so as to form a funnel-like shape connection structure between the first set of data paths and the second set of data paths.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a memory device such as a 3D DRAM device with a funnel-like I/O (input/output) repair mechanism/algorithm according to an embodiment of the invention.

FIG. 2 is a diagram of a memory device such as a 3D DRAM device with the funnel-like I/O (input/output) repair mechanism/algorithm according to another different embodiment of the invention.

FIG. 3 is a diagram of an example of the decoder in FIG. 1 executing the funnel-like I/O repair mechanism/algorithm according to an embodiment of the invention.

FIG. 4 is a diagram of a simplified example of the decoder controlling the multiplexer circuit to select the shifted connection position if the data path is a faulty data path according to another different embodiment of the invention.

### DETAILED DESCRIPTION

The present invention aims at providing a funnel-like shape input/output (I/O) repair mechanism which is capable of simplifying the trace routing design.

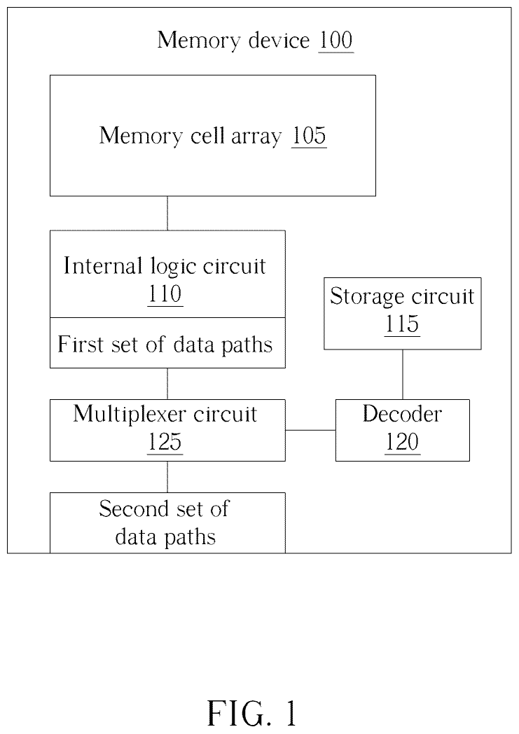

FIG. 1 is a diagram of a memory device 100 such as a 3D DRAM device with a funnel-like shape I/O (input/output) repair mechanism/algorithm according to an embodiment of the invention. The memory device 100, e.g. a high capacity storage device such as 3D DRAM, comprises a memory cell array 105, an internal logic circuit 110 having a first set of data paths (e.g. I/O data paths), a second set of data paths (e.g. I/O data paths), a storage circuit 115, a decoder 120, and a multiplexer circuit 125.

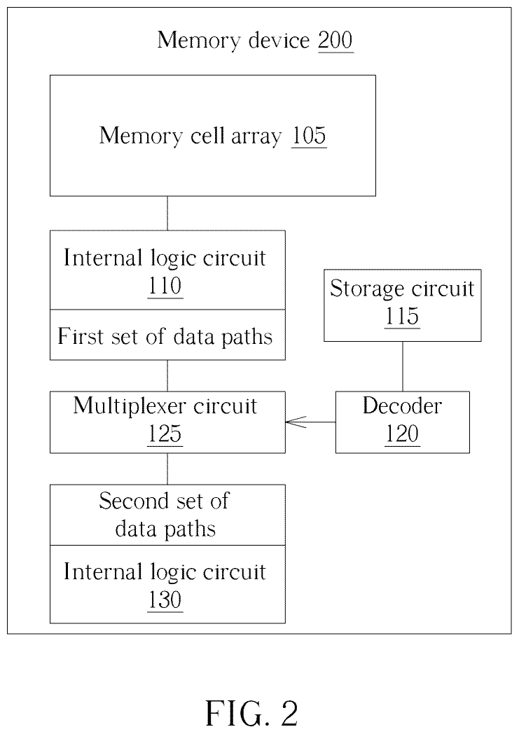

The memory cell array 105 is used for storing data which can be accessed. The first set of data paths (or called data lanes) of the internal logic circuit 110 are coupled to the memory cell array. The second set of data paths which can be output pads of the memory device 100. Alternatively, the second set of data paths may be data paths of another internal logic circuit 130 that may be a cache circuit/module or a CIM circuit/module as shown in the memory device 200 of FIG. 2 wherein the cache circuit is a small and fast memory circuit such as SRAM can be used to store the frequently used data next to a processing unit such as CPU to reduce the access time while the CIM circuit is a compute-in-memory circuit which is used to perform computations (such as math calculations) directly inside the memory device to eliminate the requirements to move data. FIG. 2 is a diagram of a memory device 200 such as a 3D DRAM device with the funnel-like shape I/O (input/output) repair mechanism/algorithm according to another different embodiment of the invention.

The number of the first set of data paths is larger than the number of the second set of data paths. For example, the first set of data paths may include (N+1) main data paths and m redundant data paths, and the second set of data paths may comprise (N+1) main data paths which respectively correspond to the (N+1) main data paths in the first set in an initial default setting.

The storage circuit 115 is used to store one or more sets of bits indicating fault information that indicates which data path(s) in the first set is/are faulty/defective data paths to be repaired (i.e. to be replaced by other non-defective data paths). For example (but not limited), the one or more sets of bits can determined during a wafer probing/sort stage of manufacturing of the memory device 100, e.g. after the silicon wafer is fabricated and before the individual chips/dies are cut apart and encapsulated in the packaging. For example, a wafer probe machine may instruct a chip/die (e.g. the internal logic circuit 110 mentioned above) to enter a test mode, and in the test mode the internal logic circuit's 100 internal BIST (built-in self-test) circuit is activated to run tests on its all I/O (input/output) data paths such as (N+1) main data paths and m redundant data paths to detect any timing skew faults or signal integrity faults. When the internal BIST circuit detects a faulty data path, the internal BIST circuit may record store and the corresponding bits indicating the serial number of the detected faulty data path as one set of bits in the storage circuit 115. The storage circuit 115 is for example an eFuse (electronic fuse) circuit to permanently store and record the one or more sets of bits which indicate which data path(s) in the first set is/are faulty.

The decoder 120 is coupled to the storage circuit 115 and is used to read the one or more sets of bits (i.e. the fault information) from the storage circuit 115 to decode the read bits to obtain and know the information of which data path(s) is/are faulty data paths to be replaced.

The decoder 120, i.e. an on-chip internal analysis circuit, may obtain and know that information of which data path(s) is/are faulty data paths to be repaired/replaced based on the read bits. Then, the decoder 120 is used to determine the repair solution based on a funnel-like shape I/O repair mechanism/algorithm provided by the present invention. That is, the decoder 120 operates based on the provided funnel-like shape I/O repair mechanism/algorithm to determine which non-faulty data path(s) should be used to respectively replace the corresponding faulty data path(s) indicated by the read bits. It should be noted that in the embodiment the decoder 120 does not directly use the redundant data path(s) to replace the faulty data path(s) in the first set.

The multiplexer circuit 125 is disposed between the first set of data paths of the internal logic circuit 110 and the second set of data paths (the data paths of the another internal logic circuit 130 in FIG. 2 or output data paths/pads in FIG. 1). The decoder 120 controls the multiplexer circuit 125 to select the non-faulty data path(s) to form connections so as to respectively replace the original connections of the corresponding faulty data path(s) based on the funnel-like shape I/O repair mechanism/algorithm.

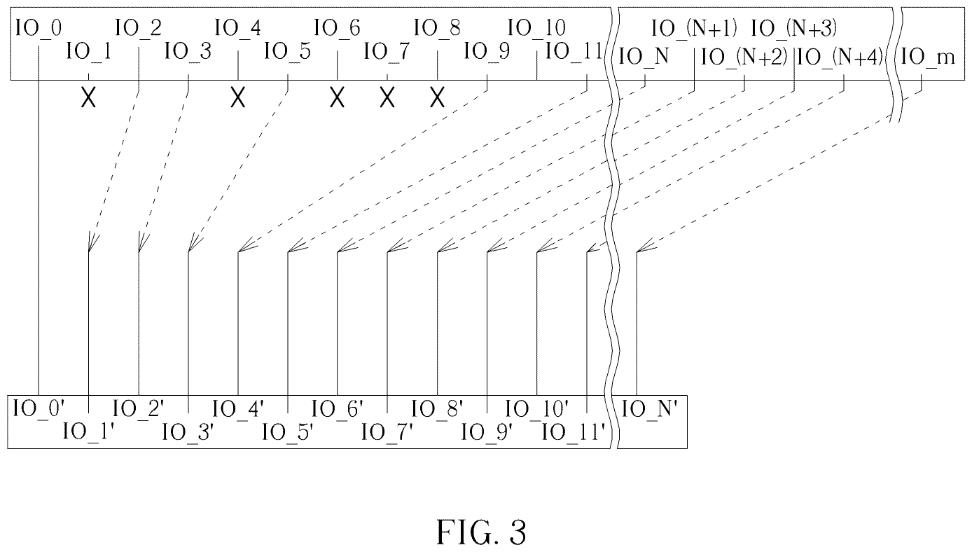

FIG. 3 is a diagram of an example of the decoder in FIG. 1 executing the funnel-like shape I/O repair mechanism/algorithm according to an embodiment of the invention. In FIG. 3, the first set of data paths may comprise (N+1) main data paths indicated by the serial numbers IO_0, IO_1, . . . , and IO_N and further comprise m redundant/spare data paths indicated by the serial numbers IO_(N+1), IO_(N+2), . . . , IO_(N+m). The second set of data paths may also comprise (N+1) main data paths indicated by the serial numbers IO_0', IO_1′, . . . , and IO_N′.

In an ideal default setting, if the main data paths of the internal logic circuit 110 are not faulty, then the (N+1) main data paths IO_0, IO_1, . . . , and IO_N of the internal logic circuit 110 may be respectively designed to correspond to and connected to the (N+1) main data paths IO_0′, IO_1′, . . . , and IO_N′ of the another internal logic circuit 130 or connected to the output data pads/pins IO_0′, IO_1′, . . . , and IO_N′. In practice, when at least one faulty data path is determined as defective data path(s) after testing, the decoder 120 of FIG. 1 or FIG. 2 is arranged to control the multiplexer circuit 125 to bypass at least one defective data path, shift at least one connection position into a next non-defective data path, and accumulate the shifted connection positions from the left data path to the right data path. That is, in this embodiment, a next and neighboring non-defective main data path is determined by the decoder 120 as a repair solution to replace a previous defective data path. The decoder 120 does not directly use the redundant data path to replace the defective main data path.

For example (but not limited), in the embodiment of FIG. 3, the decoder 120 obtains the multiple sets of bits from the storage circuit 115, and can decode the multiple sets of bits to obtain the information indicating that the data paths IO_1, IO_4, IO_6, IO_7, IO_8, IO_10 in the first set are faulty data paths indicated by ‘X’ in FIG. 3. Then, the decoder 120 is arranged to sequentially determine which non-faulty data path is to be connected to each data paths IO_0′-IO_N′ from the left to the right based on the funnel-like shape I/O repair mechanism/algorithm so as to repair the faulty connection in an original default setting.

For instance, the data path IO_0′ in the second set is determined by the decoder 120 to be connected to the data path IO_0 in the first set. The data path IO_1′ in the second set is determined by the decoder 120 to be connected to the data path IO_2 in the first set since the data path IO_1 in the first set is a faulty data path and the decoder 120 controls the multiplexer circuit 125 to shift one connection position from the left to the right and accumulates the number of shifted connection positions as-1 (the minus symbol indicates the shift direction is from the left to the right).

Then, the data path IO_2′ in the second set is determined by the decoder 120 to be connected to the data path IO_3 in the first set since the data path IO_3 in the first set is a non-faulty data path and the decoder 120 does not control the multiplexer circuit 125 to shift for one more time and thus the accumulated number of shifted connection positions (e.g. −1) indicates that the serial number of the connection position is merely to be shifted by one.

Then, the data path IO_3′ in the second set is determined by the decoder 120 to be connected to the data path IO_5 in the first set since the data path IO_4 (next to the data path IO_3) in the first set is a faulty data path and the decoder 120 controls the multiplexer circuit 125 to shift for one more time and thus the accumulated number of shifted connection positions (e.g. −2) indicates that the serial number of the connection position is to be shifted by two.

Then, the data path IO_4′ in the second set is determined by the decoder 120 to be connected to the data path IO_9 in the first set since the threes data paths IO_6, IO_7, IO_8 (next to the data path IO_5) in the first set are faulty data paths and the decoder 120 controls the multiplexer circuit 125 to shift for three more times and thus the accumulated number of shifted connection positions (e.g. −5) indicates that the serial number of the connection position is to be shifted by five. It should be noted that a serial number (e.g. IO_9) of the neighboring non-faulty data path selected by the decoder 120 is larger than a serial number (e.g. IO_5) of the specific data path, and no non-faulty data paths occur between the neighboring non-faulty data path (e.g. IO_9) and the specific data path (e.g. IO_5).

Then, the data path IO_5′ in the second set is determined by the decoder 120 to be connected to the data path IO_11 in the first set since the data path IO_10 (next to the data path IO_9) in the first set is a faulty data path and the decoder 120 controls the multiplexer circuit 125 to shift for one more time and thus the accumulated number of shifted connection positions (e.g. −6) indicates that the serial number of the connection position is to be shifted by six.

Similarly, the data paths IO_6′, IO_7′, IO_8′, IO_9′, IO_10′, IO_11′, . . . , IO_N′ in the second set are determined by the decoder 120 to be respectively connected to the data paths IO_N, IO_(N+1), IO_(N+2), IO_(N+3), IO_(N+4), IO_(N+5), . . . , IO_(N+m) in the first set since the accumulated number of shifted connection positions (e.g. −6) indicates that the serial numbers of the connection positions should be shifted by six. For example (but not limited), in this simplified example, the value N may be 12, and the value m may be 6. However, this is not intended to be a limitation.

By doing so, the decoder 120 can execute the funnel-like shape I/O repair mechanism/algorithm to control the multiplexer circuit 125 to form the funnel-like shape connection structure of the data paths in FIG. 3, and the connection structure indicates a funnel-like shape. It should be noted that the decoder 120 does not directly control the multiplexer circuit 125 to directly use the connection path of a redundant data path to replace the faulty connection path of a faulty data path. The decoder 120 is arranged to select and use the connection path of a non-faulty data path, which is neighboring to the faulty data path, as a repair solution to replace the faulty connection path of the faulty data path.

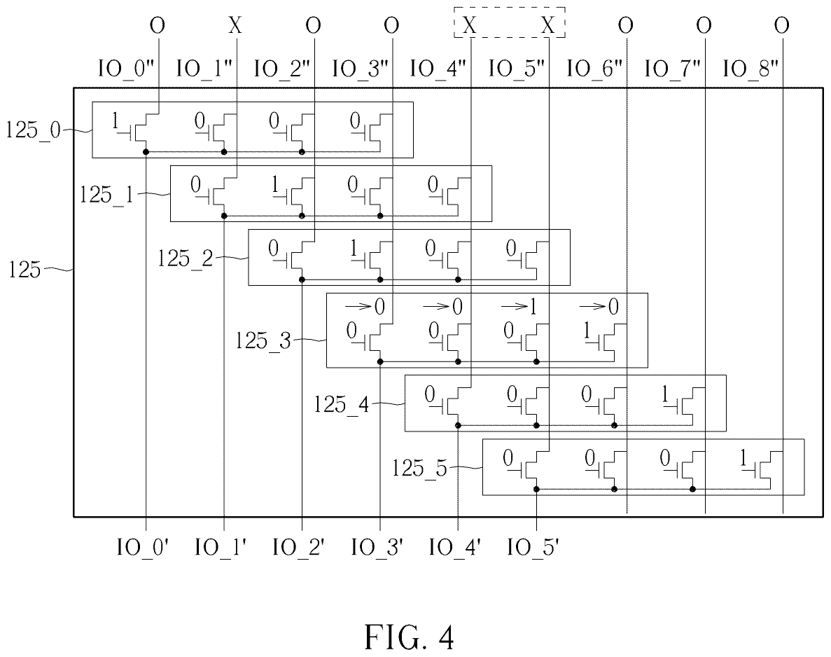

FIG. 4 is a diagram of a simplified example of the decoder 120 controlling the multiplexer circuit 125 to select the shifted connection position if the data path is a faulty data path according to another different embodiment of the invention. In FIG. 4, the multiplexer circuit 125 comprises multiple multiplexers 125_0, 125_1, 125_2, 125_3, 125_4, and 125_5, and each multiplexer comprises for example four transistors (but not limited), and the four transistors are connected in parallel wherein the four transistors have first terminals respectively coupled to four adjacent data paths in the first set, have second terminals together coupled to a specific data path in the second set, and have four control terminals respectively coupled to and controlled by the voltage levels corresponding to the control signal generated from the decoder 120. The number of multiplexers comprised by the multiplexer circuit 125 is equal to the number of second set of data paths IO_0′-IO_5′ in FIG. 4 while the first set of data paths are indicated for example by IO_0″-IO_8″ in FIG. 4. As shown in FIG. 4, ‘O’ indicates a non-faulty data path while ‘X’ indicates a faulty data path. That is, in this situation, the first set of data paths of the internal logic circuit may comprise the data paths IO_0″-IO_8″, and the data paths IO_0″, IO_2″, IO_3″, IO_6″, IO_7″, IO_8″ are non-faulty data paths while the other data paths IO_1″, IO_4″, IO_5″ are faulty data paths.

The decoder 120 generates control signals each including four bits corresponding to high/low voltage levels, and a bit ‘0’ is associated with a low voltage level such as ground level while a bit ‘1’ is associated with a high voltage level such as a voltage higher than a threshold voltage of a transistor and can be used to enable such transistor. For example, for the data path IO_0′ in the second set, the decoder 120 generate the four bits ‘1000’ to enable a first transistor and disable the other transistors in the first multiplexer 125_0, so that the data path IO_0″ in the first set can be connected to the data path IO_0′ in the second set through the enabled transistor of the first multiplexer 125_0.

For the data path IO_1′ in the second set, since the data path IO_1″ in the first set is a defective data path, the decoder 120 finds and obtains a next and neighboring non-defective data pad IO_2'′ in the first set and thus bypasses the defective data path IO_1′ to shift the connection position by one. In this situation, the decoder 120 shifts the bit position of bit ‘1’ in the previous four bits (i.e. ‘1000’) from the left to the right by one so as to generate and update the four bits ‘0100’ of the control signal. Thus, the decoder 120 can enable a second transistor and disable the other three transistors in the second multiplexer 125_1, so that the data path IO_1′ in the second set can be connected to the data path IO_2″ in the first set through the enabled transistor of the second multiplexer 125_1.

For the data path IO_2′ in the second set, since the next and neighboring data path IO_3″ in the first set is non-defective, the decoder 120 at this time does not shift the connection position by one again. In this situation, the decoder 120 does not update the previous four bits of the control signal and generates the four bits ‘0100’ of the control signal. Thus, the decoder 120 can enable a second transistor and disable the other three transistors in the third multiplexer 125_2, so that the data path IO_2′ in the second set can be connected to the data path IO_3″ in the first set through the enabled transistor of the third multiplexer 125_2.

For the data path IO_3′ in the second set, since the next and neighboring two data paths IO_4″ and IO_5″ in the first set is defective while the data path IO_6″ in the first set is non-defective, the decoder 120 finds and obtain a next and neighboring non-defective data path is data path IO_6″ in the first set and thus bypasses the defective data paths IO_4″ and IO_5″ to shift the connection position by one for two times. In this situation, the decoder 120 shifts the bit position of bit ‘1’ in the previous four bits (i.e. ‘0100’) from the left to the right by one for two times (i.e. ‘0100’->‘0010’->‘0001’) so as to generate and update the four bits of the control signal as ‘0001’. Thus, the decoder 120 can enable a fourth transistor and disable the other three transistors in the fourth multiplexer 125_3, so that the data path IO_3′ in the second set can be connected to the data path IO_6″ in the first set through the enabled transistor of the fourth multiplexer 125_3.

Then, for the data path IO_4′ in the second set, since the next and neighboring data path IO_7″ in the first set is non-defective, the decoder 120 at this time does not shift the connection position by one again. In this situation, the decoder 120 does not update the previous four bits of the control signal and generates the four bits ‘0001’ of the control signal. Thus, the decoder 120 can enable a fourth transistor and disable the other three transistors in the fifth multiplexer 125_4, so that the data path IO_4′ in the second set can be connected to the data path IO_7″ in the first set through the enabled transistor of the fifth multiplexer 125_4.

Similarly, for the data path IO_5′ in the second set, since the next and neighboring data path IO_8″ in the first set is non-defective, the decoder 120 at this time does not shift the connection position by one again. In this situation, the decoder 120 does not update the previous four bits of the control signal and generates the four bits ‘0001’ of the control signal. Thus, the decoder 120 can enable a fourth transistor and disable the other three transistors in the sixth multiplexer 125_5, so that the data path IO_5′ in the second set can be connected to the data path IO_8″ in the first set through the enabled transistor of the sixth multiplexer 125_5.

By doing so, the decoder 120 is used to bypass a specific data path (e.g. a faulty data path) by shifting positions of the different bits of the control signal generated from the decoder 120. The invention can be applied into a wide I/O interface architecture/system that may use a very large number of parallel data paths such as pins or lanes to transfer a massive amount of data simultaneously. The defective data path(s) can be replaced by the repair solution (i.e. neighboring non-faulty data paths) of data paths based on the funnel-like shape IO (I/O) repair mechanism/algorithm which can be used to make the actual physical connections between the data paths of the internal logic circuit 110 and the data paths of the another internal logic circuit 130 to form a funnel-like shape which indicates the lengths of the actual physical connections can be identical as long as possible. Alternatively, the funnel-like shape (I/O) repair mechanism can be also used to make the actual physical connections between the data paths of the internal logic circuit 110 and the output data pads/pins to form the funnel-like shape which indicates the lengths of the actual physical connections can be identical as long as possible. This can simplify the trace routing design between the first set of data paths and the second set of data paths.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory device, comprising:
a memory cell array, for storing data;
an internal logic circuit having a first set of data paths, coupled to the memory cell array;
a second set of data paths, a number of the second set of data paths being smaller than a number of the first set of data paths;
a multiplexer circuit, disposed between the first set of data paths and the second set of data paths;
a storage circuit, for storing at least one set of bits indicating fault information associated with the first set of data paths; and
a decoder, coupled to the storage circuit, for reading and decoding the at least one set of bits from the storage circuit to obtain the fault information and for controlling the multiplexer circuit to select a neighboring non-faulty data path in the first set of data paths to form a connection with a data path in the second set of data paths based on the fault information if a specific data path in the first set of data paths is faulty, so as to form a funnel-like shape connection structure between the first set of data paths and the second set of data paths.

2. The memory device of claim 1, wherein the second set of data paths are input/output data pads of the memory device.

3. The memory device of claim 1, wherein the second set of data paths are input/output data paths of another internal logic circuit included within the memory device.

4. The memory device of claim 1, wherein the decoder is arranged to control the multiplexer circuit to bypass the specific data path, which is determined as a faulty data path, in the first set of data paths, shift a connection position by one, accumulate a shifted connection position, and select the neighboring non-faulty data path in the second set of data paths based on the shifted connection position which is accumulated.

5. The memory device of claim 1, wherein the first set of data paths comprise first main data paths and redundant data paths following the first main data paths, and the second set of data paths comprise second main data paths respectively corresponding to the first main data paths in an initial default setting; and, the neighboring non-faulty data path selected by the decoder and the specific data path are in the first main data paths.

6. The memory device of claim 1, wherein a serial number of the neighboring non-faulty data path selected by the decoder is larger than a serial number of the specific data path, and no non-faulty data paths occur between the neighboring non-faulty data path and the specific data path.

7. The memory device of claim 1, wherein the multiplexer circuit comprises multiple multiplexers each comprising multiple transistors being connected in parallel; the multiple transistors have first terminal respectively coupled to multiple data paths in the first set of data paths, have second terminals together coupled to a data path in the second set of data paths, and have control terminals respectively coupled to voltage level corresponding to different bits of a control signal generated from the decoder; and, the decoder is used to generate the control signal to enable a specific transistor and disable other transistors in the multiple transistors to select a connection between a data path in the first set of data paths and the data path in the second set of data paths.

8. The memory device of claim 7, wherein the decoder is used to bypass the specific data path by shifting positions of the different bits of the control signal.

9. An input/output data path repair method of a memory device, comprising:
providing a memory cell array for storing data;
providing an internal logic circuit having a first set of data paths which is coupled to the memory cell array;
providing a second set of data paths, a number of the second set of data paths being smaller than a number of the first set of data paths;
providing a multiplexer circuit which is disposed between the first set of data paths and the second set of data paths;
providing a storage circuit for storing at least one set of bits indicating fault information associated with the first set of data paths; and
using a decoder to read and decode the at least one set of bits from the storage circuit to obtain the fault information and to control the multiplexer circuit to select a neighboring non-faulty data path in the first set of data paths to form a connection with a data path in the second set of data paths based on the fault information if a specific data path in the first set of data paths is faulty, so as to form a funnel-like shape connection structure between the first set of data paths and the second set of data paths.

10. The input/output data path repair method of claim 9, wherein the second set of data paths are input/output data pads of the memory device.

11. The input/output data path repair method of claim 9, wherein the second set of data paths are input/output data paths of another internal logic circuit included within the memory device.

12. The input/output data path repair method of claim 9, wherein the step of using the decoder comprises:
using the decoder to control the multiplexer circuit to bypass the specific data path, which is determined as a faulty data path, in the first set of data paths, shift a connection position by one, accumulate a shifted connection position, and select the neighboring non-faulty data path in the second set of data paths based on the shifted connection position which is accumulated.

13. The input/output data path repair method of claim 9, wherein the first set of data paths comprise first main data paths and redundant data paths following the first main data paths, and the second set of data paths comprise second main data paths respectively corresponding to the first main data paths in an initial default setting; and, the neighboring non-faulty data path selected by the decoder and the specific data path are in the first main data paths.

14. The input/output data path repair method of claim 9, wherein a serial number of the neighboring non-faulty data path selected by the decoder is larger than a serial number of the specific data path, and no non-faulty data paths occur between the neighboring non-faulty data path and the specific data path.

15. The input/output data path repair method of claim 9, wherein the multiplexer circuit comprises multiple multiplexers each comprising multiple transistors being connected in parallel; the multiple transistors have first terminal respectively coupled to multiple data paths in the first set of data paths, have second terminals together coupled to a data path in the second set of data paths, and have control terminals respectively coupled to voltage level corresponding to different bits of a control signal generated from the decoder; and, the control signal, generated from the decoder, is to enable a specific transistor and disable other transistors in the multiple transistors to select a connection between a data path in the first set of data paths and the data path in the second set of data paths.

16. The input/output data path repair method of claim 15, further comprising:
using the decoder to bypass the specific data path by shifting positions of the different bits of the control signal.
